(19) United States
(12) Patent Application Publication
(10) Pub. No.: US 2026/0344000 A1
(43) Pub. Date: Oct. 29, 2026

(54) SEMICONDUCTOR DEVICE AND FABRICATION METHOD THEREOF

(71) Applicant: INNOSCIENCE (SUZHOU) SEMICONDUCTOR CO., LTD., Suzhou (CN)

(72) Inventors: Tao Sun, Suzhou (CN); Xue Zhang, Suzhou (CN); Jiansong Wei, Suzhou (CN)

(21) Appl. No.: 19/699,968

(22) Filed: Jun. 5, 2026

Related U.S. Application Data
(63) Continuation of application No. PCT/CN2025/098291, filed on May 30, 2025.

(30) Foreign Application Priority Data
Aug. 16, 2024 (CN) 202411127556.7

(51) Int. Cl. H10D 64/64; H10D 30/01; H10D 30/47; H10D 62/85; H10D 64/01

(52) U.S. Cl. CPC H10D 64/64; H10D 30/015; H10D 30/475; H10D 62/8503; H10D 64/0124

(57) ABSTRACT

Provided are a semiconductor device and a fabrication method thereof. The semiconductor device includes a substrate, a semiconductor epitaxial layer, and a gate structure. The semiconductor epitaxial layer is located on a side of the substrate and includes a first nitride semiconductor layer and a second nitride semiconductor layer. A bandgap of the first nitride semiconductor layer is different from a bandgap of the second nitride semiconductor layer. The gate structure is located on a side of the semiconductor epitaxial layer facing away from the substrate and includes a capping layer, a compensation doped protective layer and a gate electrode which are sequentially stacked. The capping layer is doped with dopant ions of a first conductivity type. The compensation doped protective layer is doped with dopant ions of the first conductivity type and dopant ions of a second conductivity type.

### CROSS-REFERENCE TO RELATED APPLICATIONS

This is a continuation of International Patent Application No. PCT/CN2025/098291, filed on May 30, 2025, which claims priority to Chinese Patent Application No. 202411127556.7 filed with the China National Intellectual Property Administration on Aug. 16, 2024, the disclosures of which are incorporated herein by reference in their entireties.

### TECHNICAL FIELD

The embodiments of the present disclosure relate to the technical field of semiconductors, and for example to a semiconductor device and a fabrication method thereof.

### BACKGROUND

Nitride-based semiconductor devices utilize heterojunction interfaces between two materials with different bandgaps to form quantum well-like structures. The quantum well-like structures accommodate two-dimensional electron gas (2DEG) regions, thus satisfying the requirements of high-power/high-frequency devices.

Nevertheless, some reliability issues still warrant attention. FIG. 1 is a schematic structural diagram of a semiconductor device provided in the related art. Referring to FIG. 1, in the related art, the semiconductor device includes a semiconductor epitaxial layer 2 and a gate structure disposed on the side of the semiconductor epitaxial layer 2 facing away from the substrate 1. The operation of the semiconductor device is controlled by the gate voltage applied to the gate structure. The gate voltage controls the on-off state of the channel. The voltage applied between the source and the drain can drive the flow of the 2DEG. When the semiconductor device is an enhancement-mode high electron mobility transistor (HEMT) device (i.e., an E‑mode HEMT), the gate structure includes a pGaN layer 3 and a gate electrode 4, and holes in the pGaN layer 3 are used to deplete the 2DEG in the underlying channel, achieving normally-off operation. The device with this structure has the following problems during operation: when a high positive voltage is applied to the gate electrode 4, the top region of the pGaN layer 3 has a high electric field; as the gate voltage further increases, most of the increased voltage falls on the Schottky junction, resulting in a high electric field at the Schottky interface; and after a long-term high gate voltage stress, the performance of the Schottky junction degrades, resulting in a series of reliability problems.

To solve the above problems, U.S. patent US9478632B2 configures the gate structure as a composite structure containing a P-type doped layer (172), an N-type doped layer (174), and a gate electrode. Specifically, an N-type doped layer is introduced between the pGaN layer 3 and the gate electrode 4 in the HEMT structure shown in FIG. 1. In this case, the N-type doped layer and the gate electrode are in direct contact, thereby eliminating the Schottky junction. However, the technical solution of this patent introduces some new additional problems, such as a distinct doping boundary between the P-type doped layer (172) and the N-type doped layer (174), as well as an increased leakage current in the gate structure caused by the direct contact between the N-type doped layer and the gate electrode.

### SUMMARY

The embodiments of the present disclosure provide a semiconductor device and a fabrication method thereof to improve the distribution of the gate electric field and enhance the reliability of the gate structure.

According to an aspect of the present disclosure, a semiconductor device is provided and includes a substrate, a semiconductor epitaxial layer, and a gate structure.

The semiconductor epitaxial layer is located on a side of the substrate. The semiconductor epitaxial layer includes a first nitride semiconductor layer and a second nitride semiconductor layer. A bandgap of the first nitride semiconductor layer is different from a bandgap of the second nitride semiconductor layer.

The gate structure is located on a side of the semiconductor epitaxial layer facing away from the substrate. The gate structure includes a capping layer, a compensation doped protective layer, and a gate electrode which are sequentially stacked. The compensation doped protective layer and the gate electrode are in a Schottky contact.

The capping layer is doped with dopant ions of a first conductivity type. The capping layer as a whole exhibits the first conductivity type. The compensation doped protective layer is doped with dopant ions of the first conductivity type and dopant ions of a second conductivity type. The compensation-doped protective layer as a whole exhibits the first conductivity type or is electrically neutral. An electrical conductivity of the first conductivity type of the capping layer is stronger than an electrical conductivity of the first conductivity type of the compensation doped protective layer.

In one or more embodiments, at least a portion of the compensation doped protective layer adjacent to the gate electrode has a weak first conductivity type or is electrically neutral.

In one or more embodiments, the capping layer and the compensation doped protective layer have the same dopant ions of the first conductivity type, and dopant ions of the first conductivity type at a top of the capping layer and dopant ions of the first conductivity type at a bottom of the compensation doped protective layer have the same concentration.

In one or more embodiments, the thickness of the compensation doped protective layer is smaller than the thickness of the capping layer.

In one or more embodiments, a ratio of the thickness of the compensation doped protective layer to the thickness of the capping layer ranges from 1:3 to 1:19.

In one or more embodiments, a doping concentration of the dopant ions of the first conductivity type in the capping layer is greater than or equal to a doping concentration of the dopant ions of the first conductivity type in the compensation doped protective layer.

In one or more embodiments, along a direction from the capping layer to the gate electrode, the doping concentration of the dopant ions of the first conductivity type in the compensation doped protective layer is gradually decreased; and a doping concentration of the dopant ions of the second conductivity type in the compensation doped protective layer is gradually increased or uniformly arranged.

In one or more embodiments, along the direction from the capping layer to the gate electrode, the doping concentration of the dopant ions of the first conductivity type in the compensation doped protective layer is uniformly arranged; and a doping concentration of the dopant ions of the second conductivity type in the compensation doped protective layer is gradually increased or uniformly arranged.

In one or more embodiments, the dopant ions of the first conductivity type are P-type dopant ions, and the dopant ions of the second conductivity type are N-type dopant ions.

In one or more embodiments, the P-type dopant ions include but are not limited to magnesium ions, carbon ions, iron ions and zinc ions, and the N-type dopant ions include but are not limited to silicon ions and oxygen ions.

In one or more embodiments, the capping layer is made of GaN, and the compensation doped protective layer is made of at least one of GaN or AlGaN.

According to another aspect of the present disclosure, a fabrication method of a semiconductor device is provided and includes the following:

A substrate is provided.

A semiconductor epitaxial layer is formed on a side of the substrate. The semiconductor epitaxial layer includes a first nitride semiconductor layer and a second nitride semiconductor layer. A bandgap of the first nitride semiconductor layer is different from a bandgap of the second nitride semiconductor layer.

A gate structure is formed on a side of the semiconductor epitaxial layer facing away from the substrate. The gate structure includes a capping layer, a compensation doped protective layer and a gate electrode which are sequentially stacked. The compensation doped protective layer and the gate electrode are in a Schottky contact. The capping layer is doped with dopant ions of a first conductivity type. The capping layer as a whole exhibits the first conductivity type. The compensation doped protective layer is doped with dopant ions of the first conductivity type and dopant ions of a second conductivity type. The compensation doped protective layer as a whole exhibits the first conductivity type or is electrically neutral. An electrical conductivity of the first conductivity type of the capping layer is stronger than an electrical conductivity of the first conductivity type of the compensation doped protective layer.

In one or more embodiments, the step of forming the gate structure on the side of the semiconductor epitaxial layer facing away from the substrate includes the following:

In a first stage, a capping layer material is deposited on the side of the semiconductor epitaxial layer facing away from the substrate, and the dopant ions of the first conductivity type are introduced into a growth environment to form the capping layer.

In a second stage after the first stage, a compensation doped protective layer material is deposited on the side of the semiconductor epitaxial layer facing away from the substrate, and the dopant ions of the first conductivity type and the dopant ions of the second conductivity type are introduced into the growth environment to form the compensation doped protective layer.

The gate electrode is formed on the side of the compensation doped protective layer facing away from the substrate.

In one or more embodiments, the step of depositing the compensation doped protective layer material on the side of the semiconductor epitaxial layer facing away from the substrate, and introducing the dopant ions of the first conductivity type and the dopant ions of the second conductivity type into the growth environment to form the compensation doped protective layer includes the following:

In the second stage, an introduction amount of the dopant ions of the first conductivity type is gradually reduced, and an introduction amount of the dopant ions of the second conductivity type is gradually increased, or the dopant ions of the second conductivity type are uniformly introduced, or an introduction amount of the dopant ions of the second conductivity type is gradually reduced.

Alternatively, in the second stage, the dopant ions of the first conductivity type are uniformly introduced, and an introduction amount of the dopant ions of the second conductivity type is gradually increased, or the dopant ions of the second conductivity type are uniformly introduced.

The embodiments of the present disclosure provide a semiconductor device and a fabrication method thereof. The semiconductor device includes a substrate, a semiconductor epitaxial layer and a gate structure. The semiconductor epitaxial layer is located on a side of the substrate. The semiconductor epitaxial layer includes a heterojunction with the 2DEG. The gate structure is located on a side of the semiconductor epitaxial layer facing away from the substrate. The gate structure includes a capping layer, a compensation doped protective layer, and a gate electrode which are sequentially stacked. The capping layer is doped with dopant ions of a first conductivity type, and the compensation doped protective layer is dope with dopant ions of the first conductivity type and dopant ions of a second conductivity type, so that an electrical conductivity of the first conductivity type of the capping layer is stronger than an electrical conductivity of the first conductivity type of the compensation doped protective layer. According to the technical solution provided by the embodiments of the present disclosure, the compensation doped protective layer is provided above the capping layer, and the compensation doped protective layer is doped with both the dopant ions of the first conductivity type and the dopant ions of the second conductivity type; thus, the electrical conductivity of the first conductivity type of the compensation doped protective layer is weakened. The compensation doped protective layer is configured to provide a lower electric field relative to the capping layer, thereby improving the distribution of the gate electric field, increasing the gate breakdown voltage, and enhancing the reliability of the gate structure.

It should be understood that the content described in this section is not intended to identify the key or important features of the embodiments of the present disclosure, nor is it intended to limit the scope of the present disclosure.

### BRIEF DESCRIPTION OF DRAWINGS

FIG. 1 is a schematic structural diagram of a semiconductor device provided in the related art.

FIG. 2 is a schematic structural diagram of a semiconductor device provided in an embodiment of the present disclosure.

FIG. 3 is a capacitance-voltage (CV) test curve comparison of a semiconductor device without a compensation doped protective layer and a semiconductor device with a compensation doped protective layer provided in an embodiment of the present disclosure.

FIG. 4 is a probability distribution comparison of gate breakdown voltages of semiconductor devices without compensation doped protective layers and gate breakdown voltages of semiconductor devices with compensation doped protective layers provided in an embodiment of the present disclosure.

FIG. 5 is another schematic structural diagram of a semiconductor device provided in an embodiment of the present disclosure.

FIG. 6 is a flowchart of a fabrication method of a semiconductor device provided in an embodiment of the present disclosure.

### DETAILED DESCRIPTION

It should be noted that the terms "first" and "second" in the description, claims and the above drawings of the present disclosure are used to distinguish similar objects, and are not necessarily used to describe a specific order or sequence. It should be understood that the numbers used in this way may be interchanged where appropriate, so that the embodiments of the present disclosure described herein may be implemented in an order other than those illustrated or described herein. Furthermore, the terms "including" and "comprising" and any variations thereof are intended to cover non-exclusive inclusion, for example, a process, method, system, product or device that includes a series of steps or elements is not necessarily limited to those steps or elements expressly listed, but may include other steps or elements not expressly listed or inherent to such process, method, product or device.

An embodiment of the present disclosure provides a semiconductor device. FIG. 2 is a schematic structural diagram of a semiconductor device provided in an embodiment of the present disclosure. Referring to FIG. 2, the semiconductor device includes a substrate 10, a semiconductor epitaxial layer 20, and a gate structure 30.

The semiconductor epitaxial layer 20 is located on a side of the substrate 10. The semiconductor epitaxial layer 20 includes a first nitride semiconductor layer 21 and a second nitride semiconductor layer 22. A bandgap of the first nitride semiconductor layer 21 is different from a bandgap of the second nitride semiconductor layer 22.

The gate structure 30 is located on a side of the semiconductor epitaxial layer 20 facing away from the substrate 10. The gate structure 30 includes a capping layer 31, a compensation doped protective layer 32, and a gate electrode 33 which are sequentially stacked. The compensation doped protective layer 32 and the gate electrode 33 are in a Schottky contact.

The capping layer 31 is doped with dopant ions of a first conductivity type, and the capping layer 31 as a whole exhibits the first conductivity type. The compensation doped protective layer 32 is doped with dopant ions of the first conductivity type and dopant ions of a second conductivity type, and the compensation doped protective layer 32 as a whole exhibits the first conductivity type or is electrically neutral. An electrical conductivity of the first conductivity type of the capping layer 31 is stronger than an electrical conductivity of the first conductivity type of the compensation doped protective layer 32.

The substrate 10 may be a semiconductor substrate. The material of the substrate 10 may include, but is not limited to, Si, SiGe, SiC, gallium arsenide, P-type doped Si, N-type doped Si, sapphire, semiconductor-on-insulator (such as silicon-on-insulator (SOI)), or other suitable materials for the substrate 10. In some embodiments, the substrate 10 may include, for example, but not limited to, a group III element, a group IV element, a group V element, or a combination thereof (e.g., a III‑V compound). In other embodiments, the material of the substrate 10 may include a silicon substrate having a <111> orientation.

In some embodiments, a buffer layer 11 may be disposed between the substrate 10 and the semiconductor epitaxial layer 20, and the buffer layer 11 may be in contact with the semiconductor epitaxial layer 20. The buffer layer 11 is configured to reduce lattice and thermal mismatch between the substrate 10 and the semiconductor epitaxial layer 20, thereby solving defects caused by the mismatch/difference. The buffer layer 11 may contain a III‑V compound. The III‑V compound may include, but is not limited to, aluminum, gallium, indium, nitrogen, or a combination thereof. Therefore, exemplary materials of the buffer layer 11 may include, for example, but not limited to, GaN, AlN, AlGaN, InAlGaN, or a combination thereof. In some embodiments, a nucleation layer may be included between the substrate 10 and the semiconductor epitaxial layer 20. The nucleation layer may be formed beneath the buffer layer 11. The nucleation layer is configured to provide a transition to accommodate the mismatch/difference between the substrate 10 and the III‑nitride layer of the buffer layer 11. Exemplary materials of the nucleation layer may include, but are not limited to, AlN.

The semiconductor epitaxial layer 20 includes the first nitride semiconductor layer 21 and the second nitride semiconductor layer 22. The first nitride semiconductor layer 21 is located on a side of the substrate 10, and the second nitride semiconductor layer 22 is located on a side of the first nitride semiconductor layer 21 facing away from the substrate 10. The bandgap of the second nitride semiconductor layer 22 is different from the bandgap of the first nitride semiconductor layer 21. The heterojunction with the 2DEG may exist between the first nitride semiconductor layer 21 and the second nitride semiconductor layer 22. The material of the first nitride semiconductor layer 21 may include, but is not limited to, nitride or III‑V compounds, such as GaN, AlN, InN, InₓAl_{y}Ga(_{1-x-y})N (where x+y ≤ 1) and Al_{y}Ga_{(1-y)}N (where y≤1). The material of the second nitride semiconductor layer 22 may include, but is not limited to, III‑V nitride semiconductor materials, such as GaN, AlGaN, InN, AlInN, InGaN, AlInGaN or a combination thereof. The bandgap (i.e., bandgap width) of the material of the first nitride semiconductor layer 21 and the bandgap of the material of the second nitride semiconductor layer 22 are configured to be different so that an electronic affinity of the first nitride semiconductor layer 21 and an electronic affinity of the second nitride semiconductor layer 22 are different and a heterojunction is formed between the first nitride semiconductor layer 21 and the second nitride semiconductor layer 22.

The bandgap of the material of the first nitride semiconductor layer 21 is configured to be smaller than the bandgap of the material of the second nitride semiconductor layer 22. For example, the first nitride semiconductor layer 21 may be selected as a GaN layer with a bandgap of approximately 3.4 eV, and the second nitride semiconductor layer 22 may be selected as an AlGaN layer with a bandgap of approximately 4.0 eV. Accordingly, the first nitride semiconductor layer 21 and the second nitride semiconductor layer 22 may serve as a channel layer and a barrier layer, respectively. A triangular well potential is generated at a junction interface between the channel layer and the barrier layer, causing electrons to accumulate in the triangular well, thereby generating a 2DEG region adjacent to the heterojunction. Therefore, the semiconductor device may include at least one GaN-based HEMT. It should be noted that the formation of the 2DEG region is positively correlated with the degree of polarization effect between the channel layer and the barrier layer.

The gate structure 30 is disposed on the side of the semiconductor epitaxial layer 20 facing away from the substrate 10. The operation of the semiconductor device is controlled by the gate voltage applied to the gate structure 30, and the gate voltage controls the on-off state of the channel. The semiconductor device in the present disclosure is an enhancement-mode HEMT device (E‑mode HEMT). The gate structure 30 includes a capping layer 31, a compensation doped protective layer 32, and a gate electrode 33 which are sequentially stacked. The capping layer 31 is located on the surface of the semiconductor epitaxial layer 20 facing away from the substrate 10, the compensation doped protective layer 32 is located on the surface of the capping layer 31 facing away from the substrate 10, and the gate electrode 33 is located on the surface of the compensation doped protective layer 32 facing away from the substrate 10. The capping layer 31 is doped with the dopant ions of the first conductivity type, and the capping layer 31 has the first conductivity type. The compensation doped protective layer 32 is doped with the dopant ions of the first conductivity type and the dopant ions of the second conductivity type, and the compensation doped protective layer 32 has a first conductivity type weaker than the first conductivity type of the capping layer 31, or may be electrically neutral.

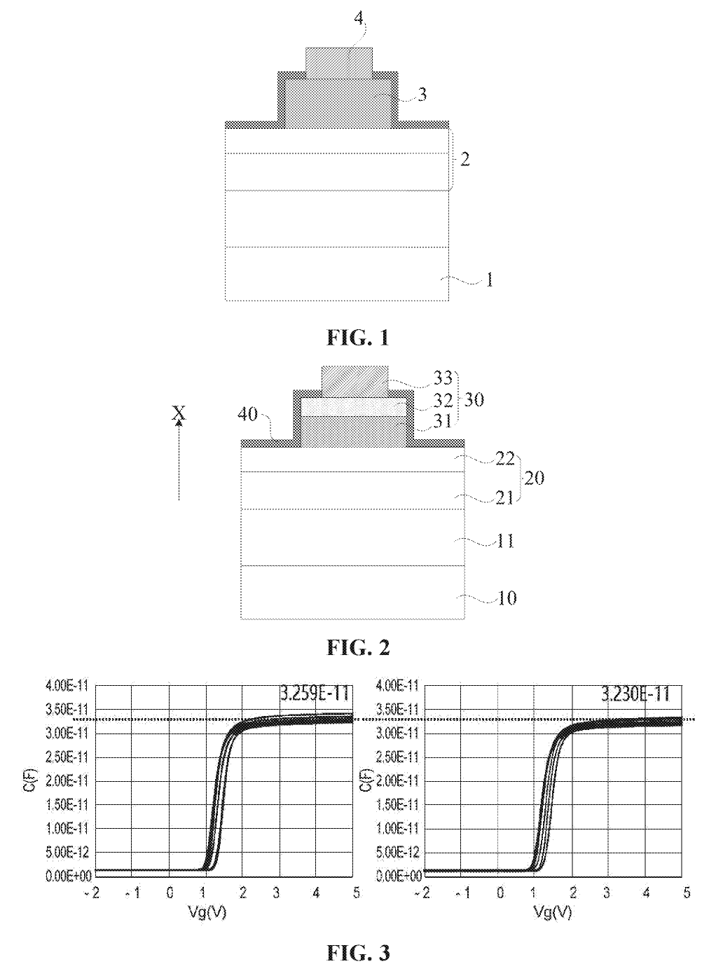

If the first conductivity type is P-type conductivity, the second conductivity type is N-type conductivity. If the first conductivity type is N-type conductivity, the second conductivity type is P-type conductivity. In the embodiments of the present disclosure, the first conductivity type is P-type conductivity, and the second conductivity type is N-type conductivity. The dopant ions of the first conductivity type are P-type dopant ions and the dopant ions of the second conductivity type are N-type dopant ions. The P-type dopant ions include, but are not limited to, magnesium (Mg) ions, carbon (C) ions, iron (Fe) ions and zinc (Zn) ions. The N-type dopant ions include, but are not limited to, silicon (Si) ions and oxygen (O) ions. The capping layer 31 is a P-type capping layer, and a hole in the P-type capping layer is configured to deplete the2DEG in the underlying channel, thereby achieving normally-off operation. The compensation doped protective layer 32 may be a weak P-type compensation doped protective layer 32 or a neutral compensation doped protective layer 32. The compensation doped protective layer 32 is configured to provide a lower electric field relative to the capping layer 31, thereby improving the distribution of the gate electric field, increasing the gate breakdown voltage and enhancing the reliability of the gate structure 30. The compensation doped protective layer 32 may be a film layer epitaxially grown between the P-type capping layer 31 and the gate electrode 33 shown in FIG. 1, or the compensation doped protective layer 32 may be formed by replacing part of a film layer of the P-type capping layer 31 adjacent to the gate electrode 33 shown in FIG. 1 with a weak P-type film layer or a neutral film layer, thereby forming the compensation doped protective layer 32.

FIG. 3 is a CV test curve comparison of a semiconductor device (shown in FIG. 1) without a compensation doped protective layer and a semiconductor device (shown in FIG. 2) with a compensation doped protective layer provided in an embodiment of the present disclosure. Referring to FIG. 3, each CV test curve on the left of FIG. 3 corresponds to a semiconductor device without a compensation doped protective layer, and these semiconductor devices belong to the same wafer. That is, the left part of FIG. 3 is a test diagram obtained by testing semiconductor devices at different positions in the wafer in the related art, in which different CV test curves correspond to semiconductor devices at different positions in the wafer. Each CV test curve on the right of FIG. 3 corresponds to a semiconductor device with a compensation doped protective layer, and these semiconductor devices belong to the same wafer. That is, the right part of FIG. 3 is a test diagram obtained by testing semiconductor devices at different positions in the improved wafer of the present disclosure, where different CV test curves correspond to semiconductor devices at different positions in the wafer. As can be seen from FIG. 3, the CV curve of the semiconductor device with the compensation doped protective layer 32 has only one step, and the capacitance is 3.230×10⁻¹¹ F, which is not significantly different from the capacitance of 3.259×10⁻¹¹ F of the conventional structure shown in FIG. 1. Therefore, the semiconductor device shown in FIG. 2 is still an E-mode HEMT device controlled by the Schottky junction.

The gate breakdown voltage of the semiconductor device provided by the embodiments of the present disclosure is significantly improved, indicating that the device has higher gate reliability. Moreover, since the compensation doped protective layer and the gate electrode in the semiconductor device still maintain the Schottky contact, the leakage current is not increased.

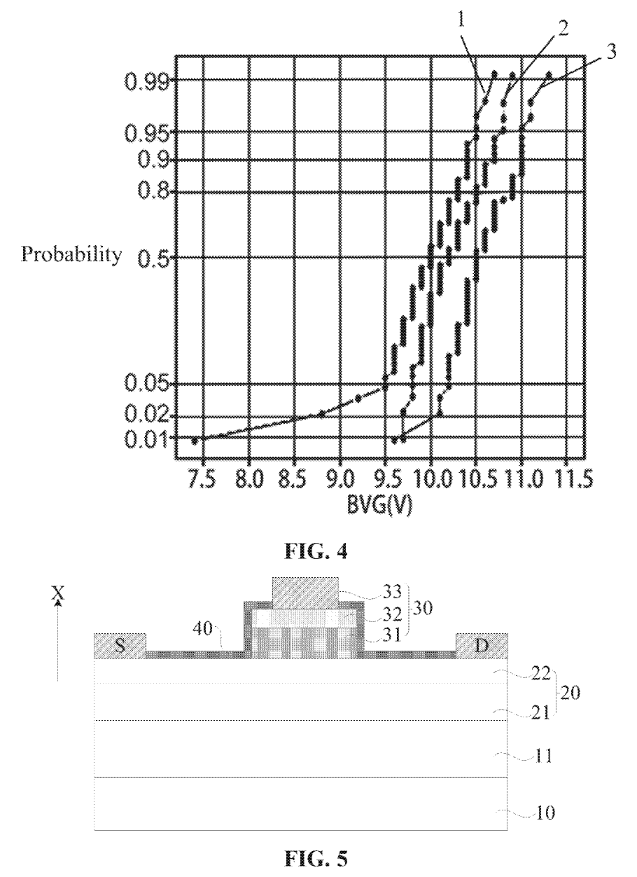

FIG. 4 is a probability distribution comparison of gate breakdown voltages of semiconductor devices without compensation doped protective layers and gate breakdown voltages of semiconductor devices with compensation doped protective layers provided in an embodiment of the present disclosure. Referring to FIG. 4, the gate breakdown voltages of multiple semiconductor devices without the compensation doped protective layers 32 are tested. Curve 1 shows the proportion of the semiconductor devices without the compensation doped protective layers 32 at different gate breakdown voltages. The breakdown voltages of multiple first semiconductor devices with the compensation doped protective layer 32 and multiple second semiconductor devices with the compensation doped protective layer 32 are tested. Curve 2 shows the proportion of the first semiconductor devices with the compensation doped protective layer 32 at different gate breakdown voltages, and curve 3 shows the proportion of the second semiconductor devices with the compensation doped protective layer 32 at different gate breakdown voltages. As can be seen from FIG. 4, the gate breakdown voltage of the semiconductor devices with the compensation doped protective layers 32 is significantly increased, indicating a higher gate reliability of the devices.

The semiconductor device provided by the embodiments of the present disclosure includes the substrate 10, the semiconductor epitaxial layer 20 located on the side of the substrate 10, and the gate structure 30 located on the side of the semiconductor epitaxial layer 20 facing away from the substrate 10. The gate structure 30 includes the capping layer 31, the compensation doped protective layer 32, and the gate electrode 33 which are sequentially stacked. The capping layer 31 is doped with the dopant ions of the first conductivity type, and the compensation doped protective layer 32 is doped with the dopant ions of the first conductivity type and the dopant ions of the second conductivity type, so that the electrical conductivity of the first conductivity type of the capping layer 31 can be stronger than the electrical conductivity of the first conductivity type of the compensation doped protective layer 32. By providing the compensation doped protective layer 32 above the capping layer 31, and doping the compensation doped protective layer 32 with both the dopant ions of the first conductivity type and the dopant ions of the second conductivity type, the technical solution provided by the embodiments of the present disclosure weakens the electrical conductivity of the first conductivity type of the compensation doped protective layer 32. The compensation doped protective layer 32 is configured to provide a lower electric field relative to the capping layer 31, thereby improving the distribution of the gate electric field, increasing the gate breakdown voltage and enhancing the reliability of the gate structure 30.

On the basis of the above embodiments, in one or more embodiments, the capping layer 31 may be a P-type doped III‑V semiconductor layer. Exemplary materials of the capping layer 31 may include P-type doped III‑V nitride semiconductor materials, such as P-type gallium nitride, P-type aluminum gallium nitride, P-type indium nitride, P-type aluminum indium nitride, P-type indium gallium nitride, P-type aluminum indium gallium nitride, or a combination thereof. In some embodiments, the P-type doped material is implemented by using P-type impurities (e.g., beryllium (Be), zinc (Zn), cadmium (Cd) and magnesium (Mg)). Exemplary materials of the gate electrode 33 may include a metal or a metal compound. The gate electrode 33 may be formed as a single layer or multiple layers having the same or different compositions. Exemplary materials of the metal or the metal compound may include, for example, but not limited to, tungsten (W), gold (Au), palladium (Pd), titanium (Ti), tantalum (Ta), cobalt (Co), nickel (Ni), platinum (Pt), molybdenum (Mo), titanium nitride (TiN), tantalum nitride (TaN), metal alloys or compounds thereof, or other metal compounds.

In one or more embodiments, the material of the capping layer 31 and the material of the compensation doped protective layer 32 are the same.

In one or more embodiments, the material of the capping layer is GaN, and the material of the compensation doped protective layer is at least one of GaN or AlGaN.

On the basis of the above embodiments, in one or more embodiments, at least a portion of the compensation doped protective layer 32 adjacent to the gate electrode 33 has a weak first conductivity type or is electrically neutral.

It can be understood that the entire compensation doped protective layer 32 may be configured to have a weak first conductivity type or to be electrically neutral. Alternatively, the top of the compensation doped protective layer 32 has a weak first conductivity type or is electrically neutral, while the first conductivity type of the rest compensation doped protective layer 32 is the same as or slightly weaker than the first conductivity type of the capping layer 31. The top of the compensation doped protective layer 32 is in contact with the gate electrode 33. Only the top of the compensation doped protective layer 32 is configured to have the weak first conductivity type or to be electrically neutral so that not only can the requirements of improving the distribution of the gate electric field, increasing the gate breakdown voltage and enhancing the reliability of the gate structure 30 be satisfied, but also the holes in the bottom of the compensation doped protective layer 32 can be used to deplete the 2DEG in the underlying channel, thereby enhancing the reliability of the device during the off state.

On the basis of the above embodiments, in one or more embodiments, the capping layer 31 and the compensation doped protective layer 32 have the same dopant ions of the first conductivity type, and dopant ions of the first conductivity type at the top of the capping layer 31 and dopant ions of the first conductivity type at the bottom of the compensation doped protective layer 32 have the same doping concentration. That the dopant ions of the first conductivity type at the top of the capping layer 31 and the dopant ions of the first conductivity type at the bottom of the compensation doped protective layer 32 have the same doping concentration can be understood as follows: the concentration of the dopant ions of the first conductivity type at the top of the capping layer 31 and the concentration of the dopant ions of the first conductivity type at the bottom of the compensation doped protective layer 32 fluctuating within ±5% of the same concentration value are considered to be the same, that is, the concentration of the dopant ions of the first conductivity type at the top of the capping layer 31 and the bottom of the compensation doped protective layer 32 are in the same preset concentration range. In this manner, the capping layer 31 and the compensation doped protective layer 32 may be fabricated by using a continuous deposition process.

On the basis of the above embodiments, in one or more embodiments, the thickness of the compensation doped protective layer 32 is smaller than the thickness of the capping layer 31. A ratio of the thickness of the compensation doped protective layer 32 to the thickness of the capping layer 31 ranges from 1:3 to 1:19. For example, when the total thickness of the gate structure is 80 nm, the thickness of the compensation doped protective layer 32 ranges from 4 nm to 20 nm, and the thickness of the capping layer 31 ranges from 60 nm to 76 nm. The thickness of the compensation doped protective layer 32 is configured to be smaller than the thickness of the capping layer 31 so that not only can the requirements of improving the distribution of the gate electric field, increasing the gate breakdown voltage and enhancing the reliability of the gate structure 30 be satisfied, but also the effect of the capping layer 31 in depleting the 2DEG in the underlying channel can be ensured, thereby enhancing the reliability of the device during the off state.

On the basis of the above embodiments, in one or more embodiments, a doping concentration of the dopant ions of the first conductivity type in the capping layer 31 is greater than or equal to a doping concentration of the dopant ions of the first conductivity type in the compensation doped protective layer 32.

The doping concentration of the dopant ions of the first conductivity type in the capping layer 31 may be greater than the doping concentration of the dopant ions of the first conductivity type in the compensation doped protective layer 32. Alternatively, the doping concentration of the dopant ions of the first conductivity type in the capping layer 31 may be equal to the doping concentration of the dopant ions of the first conductivity type in the compensation doped protective layer 32. In the embodiments of the present disclosure, the dopant ions of the second conductivity type are mixed and doped in the compensation doped protective layer 32 to weaken the electrical conductivity of the first conductivity type of the compensation doped protective layer 32, enabling the first conductivity type of the compensation doped protective layer 32 to be weaker than the first conductivity type of the capping layer 31. The compensation doped protective layer 32 is configured to provide a lower electric field relative to the capping layer 31, thereby improving the distribution of the gate electric field, increasing the gate breakdown voltage and enhancing the reliability of the gate structure 30.

In one or more embodiments, the doping concentration of the dopant ions of the first conductivity type in the capping layer 31 is greater than the doping concentration of the dopant ions of the first conductivity type in the compensation doped protective layer 32 so that the P-type ions in the compensation doped protective layer 32 can be reduced, thereby lowering the cost, and facilitating the implementation of the weak P-type compensation doped protective layer 32 or the neutral compensation doped protective layer 32. Furthermore, the reduction of the doping content of P-type ions in the compensation doped protective layer 32 can also reduce the roughness of the surface of the compensation doped protective layer 32, thus improving the crystal quality of the surface of the compensation doped protective layer 32.

On the basis of the above embodiments, in an embodiment of the present disclosure, along a direction X from the capping layer 31 to the gate electrode 33, the doping concentration of the dopant ions of the first conductivity type in the compensation doped protective layer 32 is uniformly arranged; and a doping concentration of the dopant ions of the second conductivity type in the compensation doped protective layer 32 is gradually increased or uniformly arranged.

The doping concentration of the dopant ions of the first conductivity type in the capping layer 31 is greater than or equal to the doping concentration of the dopant ions of the first conductivity type in the compensation doped protective layer 32. Along the direction X from the capping layer 31 to the gate electrode 33, the doping concentration of the dopant ions of the first conductivity type in the compensation doped protective layer 32 is uniformly arranged, and the doping concentration of the dopant ions of the second conductivity type in the compensation doped protective layer 32 is gradually decreased or uniformly arranged. According to the technical solution provided by the embodiments of the present disclosure, the doping concentration of the dopant ions of the first conductivity type in the compensation doped protective layer 32 is uniformly arranged so that no adjustment of the introduction amount of the dopant ions of the first conductivity type is required when the compensation doped protective layer 32 is doped with the dopant ions of the first conductivity type, thereby reducing the fabrication difficulty of the device.

If the dopant ions of the second conductivity type in the compensation doped protective layer 32 are uniformly arranged, the introduction amount of the dopant ions of the second conductivity type does not need to be adjusted, thus further reducing the fabrication difficulty of the device. If the doping concentration of the dopant ions of the second conductivity type in the compensation doped protective layer 32 is gradually increased along the direction X from the capping layer 31 to the gate electrode 33, the electrical conductivity of the first conductivity type of the compensation doped protective layer 32 may be gradually weakened along the direction X from the capping layer 31 to the gate electrode 33, thereby further increasing the gate breakdown voltage and enhancing the reliability of the gate structure 30.

On the basis of the above embodiments, in another embodiment of the present disclosure, along the direction X from the capping layer 31 to the gate electrode 33, the doping concentration of the dopant ions of the first conductivity type in the compensation doped protective layer 32 is gradually decreased. The doping concentration of the dopant ions of the second conductivity type in the compensation doped protective layer 32 is gradually decreased, uniformly arranged, or gradually increased.

The doping concentration of the dopant ions of the first conductivity type in the capping layer 31 is greater than the doping concentration of the dopant ions of the first conductivity type in the compensation doped protective layer 32; along the direction X from the capping layer 31 to the gate electrode 33, the doping concentration of the dopant ions of the first conductivity type in the compensation doped protective layer 32 is gradually decreased, and the doping concentration of the dopant ions of the second conductivity type in the compensation doped protective layer 32 is gradually decreased. The doping concentration of the dopant ions of the first conductivity type and the doping concentration of the dopant ions of the second conductivity type in the compensation doped protective layer 32 are configured to be gradually decreased so that the cost of the device can be further reduced. Furthermore, the reduction in the doping content of ions in the compensation doped protective layer 32 can further reduce the roughness of the surface of the compensation doped protective layer 32, thus improving the crystal quality of the surface of the compensation doped protective layer 32. In addition, the characteristic that the electrical conductivity of the first conductivity type of the compensation doped protective layer 32 is gradually weakened along the direction X from the capping layer 31 to the gate electrode 33 can be achieved by merely configuring the decreasing gradient of the doping concentration of the dopant ions of the first conductivity type to be greater than the decreasing gradient of the doping concentration of the dopant ions of the second conductivity type along the direction X from the capping layer 31 to the gate electrode 33, in the case of ensuring that the doping concentration of the dopant ions of the first conductivity type is greater than the concentration of the dopant ions of the second conductivity type at the same position in the compensation doped protective layer 32.

Alternatively, the doping concentration of the dopant ions of the first conductivity type in the capping layer 31 is greater than the doping concentration of the dopant ions of the first conductivity type in the compensation doped protective layer 32; along the direction X from the capping layer 31 to the gate electrode 33, the doping concentration of the dopant ions of the first conductivity type in the compensation doped protective layer 32 is gradually decreased, and the doping concentration of the dopant ions of the second conductivity type in the compensation doped protective layer 32 is uniformly arranged. According to the technical solution provided by the embodiments of the present disclosure, the doping concentration of the dopant ions of the first conductivity type in the compensation doped protective layer 32 is configured to be gradually decreased so that the electrical conductivity of the first conductivity type of the compensation doped protective layer 32 can be gradually weakened along the direction X from the capping layer 31 to the gate electrode 33 in the case where the doping concentration of the dopant ions of the second conductivity type in the compensation doped protective layer 32 is uniformly arranged, thereby enhancing the reliability of the gate structure 30. Moreover, since the doping concentration of the dopant ions of the first conductivity type is gradually decreased, and the doping concentration of the dopant ions of the second conductivity type is uniformly arranged, so that the difference between the doping concentration of the dopant ions of the first conductivity type and the doping concentration of the dopant ions of the second conductivity type becomes smaller along the direction X from the capping layer 31 to the gate electrode 33. In other words, the compensation effect of the dopant ions of the second conductivity type becomes stronger, thus facilitating the implementation of the neutrality at the top of the compensation doped protective layer 32. It should be emphasized that the compensation doped protective layer 32 does not exhibit N-type conductivity after compensation doping.

Alternatively, the doping concentration of the dopant ions of the first conductivity type in the capping layer 31 is greater than the doping concentration of the dopant ions of the first conductivity type in the compensation doped protective layer 32; along the direction X from the capping layer 31 to the gate electrode 33, the doping concentration of the dopant ions of the first conductivity type in the compensation doped protective layer 32 is gradually decreased, and the doping concentration of the dopant ions of the second conductivity type in the compensation doped protective layer 32 is gradually increased. According to the technical solution provided by the embodiments of the present disclosure, the doping concentration of the dopant ions of the first conductivity type in the compensation doped protective layer 32 is configured to be gradually increased so that the implementation of the characteristic that the electrical conductivity of the first conductivity type of the compensation doped protective layer 32 is gradually weakened along the direction X from the capping layer 31 to the gate electrode 33 can be facilitated, and the speed at which the electrical conductivity of the first conductivity type of the compensation doped protective layer 32 is weakened along the direction X from the capping layer 31 to the gate electrode 33 can be accelerated; in this manner, the first conductivity type at the contact position between the compensation doped protective layer 32 and the gate electrode 33 is weaker, thus facilitating the implementation of the neutrality at the top of the compensation doped protective layer 32 and enhancing the reliability of the gate structure 30.

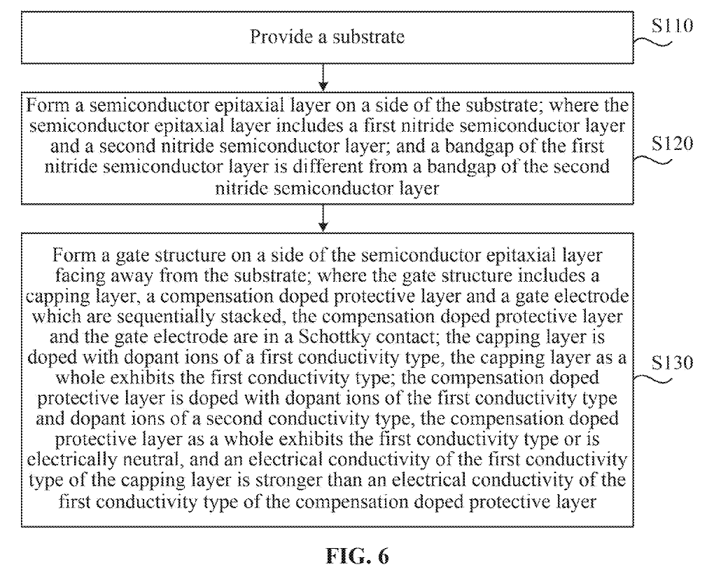

On the basis of the above embodiments, FIG. 5 is another schematic structural diagram of a semiconductor device provided in an embodiment of the present disclosure. Referring to FIG. 5, in one or more embodiments, the semiconductor device further includes a source electrode S and a drain electrode D.

The source electrode S and the drain electrode D are located on the side of the semiconductor epitaxial layer 20 facing away from the substrate 10, and are located on the opposite sides of the gate structure 30, respectively.

The source electrode S is located on the side of the second nitride semiconductor layer 22 facing away from the substrate 10 and is in contact with the second nitride semiconductor layer 22. The drain electrode D is located on the side of the second nitride semiconductor layer 22 facing away from the substrate 10 and is in contact with the second nitride semiconductor layer 22. The source electrode S and the drain electrode D are located on the opposite sides of the gate structure 30. The source electrode S and the drain electrode D may include, but are not limited to, metals, alloys, doped semiconductor materials (such as doped crystalline silicon), compounds such as silicides and nitrides, other conductor materials, or combinations thereof. The source electrode S and the drain electrode D may be a single layer or multiple layers having the same or different compositions. In some embodiments, the source electrode S and the drain electrode D form an ohmic contact with the second nitride semiconductor layer 22. The ohmic contact may be implemented by applying Ti, Al or other suitable materials to the source electrode S and the drain electrode D.

On the basis of the above embodiments, with continued reference to FIG. 5, in one or more embodiments, the semiconductor device further includes a strain layer 40 located on a sidewall of the gate structure 30, between the gate structure 30 and the source electrode S, and between the gate structure and the drain electrode D.

To further increase the concentration of the 2DEG, a strain layer 40 may be added above the semiconductor epitaxial layer 20. The stress state of AlGaN/GaN heterojunction is modulated through the strain layer 40 to reduce the on-resistance and increase the concentration of the 2DEG, thereby improving the saturation current density and the factor of merit (FOM) of the HEMT device. Furthermore, the damage to the surface of the semiconductor epitaxial layer 20 (the surface of the barrier layer) caused by the patterning process of the gate structure 30 can also be repaired through the strain layer 40, thereby reducing the defect state density on the surface of the semiconductor epitaxial layer 20, reducing the dynamic on-resistance and improving the device conversion efficiency.

The semiconductor device also includes a passivation layer. The passivation layer is located on the side of the strain layer 40 facing away from the substrate 10 and covers the surface of the strain layer 40, the surface of the gate electrode 33 and the surface of the drain electrode D. The passivation layer is made of dielectric materials such as oxides, and for example, may be made of SiO₂. The passivation layer is configured to protect and electrically insulate the semiconductor device.

The embodiments of the present disclosure also provide a fabrication method of a semiconductor device used for fabricating the semiconductor device described in any of the embodiments of the present disclosure. FIG. 6 is a flowchart of a fabrication method of a semiconductor device provided in an embodiment of the present disclosure. Referring to FIG. 6, the fabrication method of the semiconductor device includes the following:

In S110, a substrate is provided.

The substrate 10 may be a semiconductor substrate 10. The material of the substrate 10 may include, but is not limited to, Si, SiGe, SiC, gallium arsenide, P-type doped Si, N-type doped Si, sapphire, semiconductor-on-insulator (such as silicon-on-insulator (SOI)), or other suitable materials for the substrate 10. In some embodiments, the substrate 10 may include, for example, but not limited to, a group III element, a group IV element, a group V element, or a combination thereof (e.g., a III‑V compound). In other embodiments, the material of the substrate 10 may include a silicon substrate having a <111> orientation.

In S120, a semiconductor epitaxial layer is formed on a side of the substrate. The semiconductor epitaxial layer includes a first nitride semiconductor layer and a second nitride semiconductor layer. A bandgap of the first nitride semiconductor layer is different from a bandgap of the second nitride semiconductor layer.

Forming the semiconductor epitaxial layer 20 on the side of the substrate 10 includes sequentially forming the first nitride semiconductor layer 21 and the second nitride semiconductor layer 22 on the side of the substrate 10. The second nitride semiconductor layer 22 and the first nitride semiconductor layer 21 have different bandgaps, thereby enabling the heterojunction with the 2DEG to exist between the first nitride semiconductor layer 21 and the second nitride semiconductor layer 22. The material of the first nitride semiconductor layer 21 may include, but is not limited to, nitride or III‑V compounds, such as GaN, AlN, InN, InₓAl_{y}Ga(_{1-x-y})N (where x+y ≤ 1) and Al_{y}Ga_{(1-y)}N (where y ≤ 1). The material of the second nitride semiconductor layer 22 may include, but is not limited to, III‑V nitride semiconductor materials, such as GaN, AlGaN, InN, AlInN, InGaN, AlInGaN, or a combination thereof.

In one or more embodiments, before the semiconductor epitaxial layer 20 is formed on the side of the substrate 10, the fabrication method further includes forming the buffer layer 11 on the side of the substrate 10. The buffer layer 11 is located between the substrate 10 and the semiconductor epitaxial layer 20, and may be in contact with the semiconductor epitaxial layer 20. The buffer layer 11 is configured to reduce lattice and thermal mismatch between the substrate 10 and the semiconductor epitaxial layer 20, thereby solving defects caused by the mismatch/difference. The buffer layer 11 may contain a III-V compound. The III-V compound may include, but is not limited to, aluminum, gallium, indium, nitrogen, or a combination thereof. Therefore, exemplary materials of the buffer layer 11 may include, for example, but not limited to, GaN, AlN, AlGaN, InAlGaN, or a combination thereof. In some embodiments, before the buffer layer 11 is formed on the side of the substrate 10, the fabrication method further includes forming the nucleation layer on the side of the substrate 10. The nucleation layer is configured to provide a transition to accommodate the mismatch/difference between the substrate 10 and the III-nitride layer of the buffer layer 11. Exemplary materials of the nucleation layer may include, but are not limited to, any of AlN or alloys thereof.

In S130, a gate structure is formed on a side of the semiconductor epitaxial layer facing away from the substrate. The gate structure includes a capping layer, a compensation doped protective layer, and a gate electrode which are sequentially stacked. The compensation doped protective layer and the gate electrode are in a Schottky contact. The capping layer is doped with dopant ions of a first conductivity type. The capping layer as a whole exhibits the first conductivity type. The compensation doped protective layer is doped with dopant ions of the first conductivity type and dopant ions of a second conductivity type. The compensation doped protective layer as a whole exhibits the first conductivity type or is electrically neutral. An electrical conductivity of the first conductivity type of the capping layer is stronger than an electrical conductivity of the first conductivity type of the compensation doped protective layer.

The capping layer 31, the compensation doped protective layer 32 and the gate electrode 33 are sequentially formed in the gate region of the semiconductor epitaxial layer 20. The capping layer 31 is doped with the dopant ions of the first conductivity type, and the capping layer 31 has the first conductivity type. The compensation doped protective layer 32 is doped with both the dopant ions of the first conductivity type and the dopant ions of the second conductivity type, and the compensation doped protective layer 32 may have a first conductivity type weaker than the first conductivity type of the capping layer 31, or may be electrically neutral. If the first conductivity type is P-type conductivity, the second conductivity type is N-type conductivity. If the first conductivity type is N-type conductivity, the second conductivity type is P-type conductivity. In the embodiments of the present disclosure, the first conductivity type is P-type conductivity and the second conductivity type is N-type conductivity.

Exemplary materials of the capping layer 31 may include III‑V nitride semiconductor materials such as gallium nitride, aluminum gallium nitride, indium nitride, aluminum indium nitride, indium gallium nitride, aluminum indium gallium nitride, or combinations thereof. The capping layer 31 and the compensation doped protective layer 32 may be made of the same material or different materials. In this embodiment, the materials of the capping layer 31 and the compensation doped protective layer 32 are the same to simplify the fabrication process of the device.

Exemplary materials of the gate electrode 33 may include a metal or a metal compound. The gate electrode 33 may be formed as a single layer or multiple layers having the same or different compositions. Exemplary materials of the metal or the metal compound may include, for example, but not limited to, tungsten (W), gold (Au), palladium (Pd), titanium (Ti), tantalum (Ta), cobalt (Co), nickel (Ni), platinum (Pt), molybdenum (Mo), titanium nitride (TiN), tantalum nitride (TaN), metal alloys or compounds thereof, or other metal compounds.

According to the fabrication method of the semiconductor device provided by the embodiments of the present disclosure, the compensation doped protective layer 32 is formed between the capping layer 31 and the gate electrode 33, and the compensation doped protective layer 32 is doped with both the dopant ions of the first conductivity type and the dopant ions of the second conductivity type; thus the electrical conductivity of the first conductivity type of the compensation doped protective layer 32 can be weakened. The compensation doped protective layer 32 is configured to provide a lower electric field relative to the capping layer 31, thereby improving the distribution of the gate electric field, increasing the gate breakdown voltage and enhancing the reliability of the gate structure 30.

In one or more embodiments, the step S130 of forming the gate structure on the side of the semiconductor epitaxial layer facing away from the substrate includes the following:

In S1310, in a first stage, a capping layer material is deposited on the side of the semiconductor epitaxial layer facing away from the substrate, and the dopant ions of the first conductivity type are introduced into a growth environment to form the capping layer.

In S1320, in a second stage after the first stage, a compensation doped protective layer material is deposited on the side of the semiconductor epitaxial layer facing away from the substrate, and the dopant ions of the first conductivity type and the dopant ions of the second conductivity type are introduced into the growth environment to form the compensation doped protective layer.

In S1330, the gate electrode is formed on the side of the compensation doped protective layer facing away from the substrate.

Exemplary materials of the capping may III‑V nitride semiconductor materials such as gallium nitride, aluminum gallium nitride, indium nitride, aluminum indium nitride, indium gallium nitride, aluminum indium gallium nitride, or combinations thereof. Exemplary materials of the compensation doped protective layer material may include III‑V nitride semiconductor materials such as gallium nitride, aluminum gallium nitride, indium nitride, aluminum indium nitride, indium gallium nitride, aluminum indium gallium nitride, or combinations thereof. In the embodiments of the present disclosure, the capping layer 31 and the compensation doped protective layer 32 are made of the same material, and the capping layer 31 and the compensation doped protective layer 32 may be fabricated by controlling the types and amounts of ions introduced in the first stage and in the second stage.

The dopant ions of the first conductivity type are P-type dopant ions and the dopant ions of the second conductivity type are N-type dopant ions. The P-type dopant ions introduced in the first stage include, but are not limited to, magnesium ions, carbon ions, iron ions and zinc ions. In the second stage after the first stage, the P-type dopant ions and the N-type dopant ions are introduced to form the compensation doped protective layer 32. The P-type dopant ions introduced in the second stage include, but are not limited to, magnesium ions, carbon ions, iron ions and zinc ions. The introduced N-type dopant ions include, but are not limited to, silicon ions and oxygen ions.

In the second stage, introducing the dopant ions of the first conductivity type and the dopant ions of the second conductivity type into the growth environment includes the following:

In the second stage, an introduction amount of the dopant ions of the first conductivity type is gradually reduced; and an introduction amount of the dopant ions of the second conductivity type is gradually reduced, or the dopant ions of the second conductivity type are uniformly introduced, or the introduction amount of the dopant ions of the second conductivity type is gradually increased.

Alternatively, in the second stage, the dopant ions of the first conductivity type are uniformly introduced; and an introduction amount of the dopant ions of the second conductivity type is gradually increased, or the dopant ions of the second conductivity type are uniformly introduced.

In an example, the compensation doped protective layer 32 with a gradually decreased P-type ion doping concentration is formed above the P-type capping layer 31. Attributed to a stronger memory effect of Mg, a gradually weaker P-type ion doping concentration can be realized through the regulation in steps. P-type doping is implemented by gradually reducing the introduction amount of the magnesium ion source until the magnesium ion source is turned off. However, these methods are still difficult to implement P-type doping, and some N-type impurities such as silicon ions need to be doped to compensate for magnesium ions, thus implementing P-type doping. In addition, the N-type doping can also improve the crystal quality of the surface of the epitaxial layer (the compensation doped protective layer 32) and reduce the roughness of the surface.

What is claimed is:

1. A semiconductor device, comprising:
a substrate;
a semiconductor epitaxial layer located on a side of the substrate; wherein the semiconductor epitaxial layer comprises a first nitride semiconductor layer and a second nitride semiconductor layer; and a bandgap of the first nitride semiconductor layer is different from a bandgap of the second nitride semiconductor layer; and
a gate structure located on a side of the semiconductor epitaxial layer facing away from the substrate; wherein the gate structure comprises a capping layer, a compensation doped protective layer and a gate electrode which are sequentially stacked, and the compensation doped protective layer and the gate electrode are in a Schottky contact;
wherein the capping layer is doped with dopant ions of a first conductivity type, the capping layer as a whole exhibits the first conductivity type; the compensation doped protective layer is doped with dopant ions of the first conductivity type and dopant ions of a second conductivity type, the compensation doped protective layer as a whole exhibits the first conductivity type or is electrically neutral, and an electrical conductivity of the first conductivity type of the capping layer is stronger than an electrical conductivity of the first conductivity type of the compensation doped protective layer.

2. The semiconductor device according to claim 1, wherein at least a portion of the compensation doped protective layer adjacent to the gate electrode has a weak first conductivity type or is electrically neutral.

3. The semiconductor device according to claim 1, wherein the capping layer and the compensation doped protective layer have the same dopant ions of the first conductivity type, and dopant ions of the first conductivity type at a top of the capping layer and dopant ions of the first conductivity type at a bottom of the compensation doped protective layer have a same concentration.

4. The semiconductor device according to claim 1, wherein a thickness of the compensation doped protective layer is smaller than a thickness of the capping layer.

5. The semiconductor device according to claim 4, wherein a ratio of the thickness of the compensation doped protective layer to the thickness of the capping layer ranges from 1:3 to 1:19.

6. The semiconductor device according to claim 1, wherein a doping concentration of the dopant ions of the first conductivity type in the capping layer is greater than or equal to a doping concentration of the dopant ions of the first conductivity type in the compensation doped protective layer.

7. The semiconductor device according to claim 6, wherein along a direction from the capping layer to the gate electrode, the doping concentration of the dopant ions of the first conductivity type in the compensation doped protective layer is gradually decreased; and
a doping concentration of the dopant ions of the second conductivity type in the compensation doped protective layer is gradually increased, uniformly arranged, or gradually decreased.

8. The semiconductor device according to claim 6, wherein along a direction from the capping layer to the gate electrode, the doping concentration of the dopant ions of the first conductivity type in the compensation doped protective layer is uniformly arranged; and
a doping concentration of the dopant ions of the second conductivity type in the compensation doped protective layer is gradually increased or uniformly arranged.

9. The semiconductor device according to claim 1, wherein the dopant ions of the first conductivity type are P-type dopant ions, and the dopant ions of the second conductivity type are N-type dopant ions.

10. The semiconductor device according to claim 9, wherein the P-type dopant ions comprise magnesium ions, carbon ions, iron ions and zinc ions, and the N-type dopant ions comprise silicon ions and oxygen ions.

11. The semiconductor device according to claim 1, wherein a material of the capping layer comprises GaN, and a material of the compensation doped protective layer comprises at least one of GaN or AlGaN.

12. A fabrication method of a semiconductor device, comprising:
providing a substrate;
forming a semiconductor epitaxial layer on a side of the substrate; wherein the semiconductor epitaxial layer comprises a first nitride semiconductor layer and a second nitride semiconductor layer; and a bandgap of the first nitride semiconductor layer is different from a bandgap of the second nitride semiconductor layer; and
forming a gate structure on a side of the semiconductor epitaxial layer facing away from the substrate; wherein the gate structure comprises a capping layer, a compensation doped protective layer and a gate electrode which are sequentially stacked, the compensation doped protective layer and the gate electrode are in a Schottky contact; the capping layer is doped with dopant ions of a first conductivity type, the capping layer as a whole exhibits the first conductivity type; the compensation doped protective layer is doped with dopant ions of the first conductivity type and dopant ions of a second conductivity type, the compensation doped protective layer as a whole exhibits the first conductivity type or is electrically neutral, and an electrical conductivity of the first conductivity type of the capping layer is stronger than an electrical conductivity of the first conductivity type of the compensation doped protective layer.

13. The fabrication method of the semiconductor device according to claim 12, wherein forming the gate structure on the side of the semiconductor epitaxial layer facing away from the substrate comprises:
in a first stage, depositing a capping layer material on the side of the semiconductor epitaxial layer facing away from the substrate, and introducing the dopant ions of the first conductivity type into a growth environment to form the capping layer;
in a second stage after the first stage, depositing a compensation doped protective layer material on the side of the semiconductor epitaxial layer facing away from the substrate, and introducing the dopant ions of the first conductivity type and the dopant ions of the second conductivity type into the growth environment to form the compensation doped protective layer; and
forming the gate electrode on the side of the compensation doped protective layer facing away from the substrate.

14. The fabrication method of the semiconductor device according to claim 13, wherein depositing the compensation doped protective layer material on the side of the semiconductor epitaxial layer facing away from the substrate, and introducing the dopant ions of the first conductivity type and the dopant ions of the second conductivity type into the growth environment to form the compensation doped protective layer comprises:
in the second stage, gradually reducing an introduction amount of the dopant ions of the first conductivity type, and gradually reducing an introduction amount of the dopant ions of the second conductivity type, or uniformly introducing the dopant ions of the second conductivity type, or gradually increasing an introduction amount of the dopant ions of the second conductivity type; or
in the second stage, uniformly introducing the dopant ions of the first conductivity type, and gradually increasing an introduction amount of the dopant ions of the second conductivity type, or uniformly introducing the dopant ions of the second conductivity type.
